(19) United States
(12) Patent Application Publication
(10) Pub. No.: US 2024/0331584 A1
(43) Pub. Date: Oct. 3, 2024

(54) COVER WINDOW AND METHOD OF MANUFACTURING THE SAME

(71) Applicant: Samsung Display Co., LTD., Yongin-si (KR)

(72) Inventors: Jong Hyeon CHOI, Yongin-si (KR); Gwang Taek LEE, Yongin-si (KR)

(73) Assignee: Samsung Display Co., LTD., Yongin-si (KR)

(21) Appl. No.: 18/621,637

(22) Filed: Mar. 29, 2024

(30) Foreign Application Priority Data
Mar. 31, 2023 (KR) 10-2023-0042778

(51) Int. Cl. G09F 9/30; C09J 5/02; C09J 7/40

(52) U.S. Cl. CPC G09F 9/301; C09J 5/02; C09J 7/40; C09J 2301/16

(57) ABSTRACT

A cover window includes a folding area and a non-folding area arranged in a first direction, and groove patterns disposed on a substrate in the folding area, arranged in the first direction, and extending in a second direction intersecting the first direction. A central portion of the groove patterns may be filled with a first resin, and an edge portion of the groove patterns may be filled with the first resin and a second resin different from the first resin.

### CROSS REFERENCE TO RELATED APPLICATION(S)

This application claims priority to and benefits of Korean Patent Application No. 10-2023-0042778 under 35 U.S.C. § 119, filed on Mar. 31, 2023, in the Korean Intellectual Property Office (KIPO), the entire content of which are incorporated herein by reference.

### BACKGROUND

### 1. Technical Field

Embodiments relate to a cover window and a method of manufacturing the cover window.

### 2. Description of the Related Art

A display device provides information to a user by displaying various images on a display screen. In general, the display device displays information in an allocated screen.

Recently, various types of foldable flexible display devices have been developed. A shape of the flexible display device may be variously changed such as being folded, rolled, bent, or the like, and thus the flexible display device has a characteristic of being easy to carry. The flexible display device may include a foldable cover window.

In order to improve a folding characteristic, a pattern may be formed in a folding area of the cover window. In addition, in order to prevent the pattern from being recognized by a user, the pattern may be filled with a resin.

### SUMMARY

A central portion of the above-described cover window may be completely filled with the resin, but an edge portion may not be completely filled with the resin. Accordingly, a visibility difference may occur between the central portion and the edge portion of the cover window, and thus visibility may be deteriorated.

Embodiments provide a cover window and a method of manufacturing the cover window with improved visibility.

According to an embodiment of the disclosure, a cover window may include a folding area and a non-folding area arranged in a first direction, and groove patterns disposed on a substrate in the folding area, arranged in the first direction, and extending in a second direction intersecting the first direction. A central portion of the groove patterns may be filled with a first resin, and an edge portion of the groove patterns may be filled with the first resin and a second resin different from the first resin.

A viscosity of the first resin may be less than or equal to about 20 cp, and a viscosity of the second resin may be greater than or equal to about 2000 cp.

The cover window may further include an upper layer disposed on an upper surface of the substrate and having an edge portion protruding from the folding area of the upper layer, and a lower layer disposed on a lower surface of the substrate and having an edge portion protruding from the folding area of the upper layer. A gap between the edge portion of the upper layer and the edge portion of the lower layer may be filled with the second resin.

A length of the edge portion of the upper layer and a length of the edge portion of the lower layer in the second direction may be same.

Each of the length of the edge portion of the upper layer and the length of the edge portion of the lower layer may be less than or equal to about 50 μm.

The groove patterns may include first groove patterns spaced apart from each other and formed on an upper surface of the substrate, and second groove patterns spaced apart from each other and formed on a lower surface of the substrate.

The first groove patterns and the second groove patterns may be alternately arranged in the first direction.

The upper layer may include an upper adhesive layer disposed on the upper surface of the substrate, and a protective layer disposed on the upper adhesive layer.

The lower layer may include a lower adhesive layer disposed on the lower surface of the substrate, and a release layer disposed on the lower adhesive layer.

According to an embodiment of the disclosure, a method of manufacturing a cover window including a folding area and a non-folding area arranged in a first direction may include forming first groove patterns spaced apart from each other on an upper surface of a substrate in the folding area, forming second groove patterns spaced apart from each other on a lower surface of the substrate in the folding area, filling the first groove patterns with a first resin, disposing an upper layer including an edge portion protruding from the folding area of the upper layer on the upper surface of the substrate, filling the second groove patterns with the first resin, disposing a lower layer including an edge portion protruding from the folding area of the lower layer on the lower surface of the substrate, and filling a gap between the edge portion of the upper layer and the edge portion of the lower layer with a second resin different from the first resin.

The first groove patterns and the second groove patterns may be alternatively arranged in the first direction and may extend in a second direction intersecting the first direction.

A central portion of the first groove patterns and a central portion of the second groove patterns may be filled with the first resin, and an edge portion of the first groove patterns and an edge portion of the second groove patterns may be filled with the first resin and the second resin.

A viscosity of the first resin may be less than or equal to about 20 cp, and a viscosity of the second resin may be greater than or equal to about 2000 cp.

The first resin may be discharged from a first filler disposed above the first groove patterns and the second groove patterns.

The first filler may be an inkjet printing device.

The second resin may be discharged from a second filler disposed at a side of the first groove patterns and the second groove patterns.

The second filler may be a jetting valve.

Each of a length of the edge portion of the upper layer and a length of the edge portion of the lower layer may be in a range of about 1.5 mm to about 4 mm.

The method may further include cutting the edge portion of the upper layer and the edge portion of the lower layer along a cutting line.

After the cutting of the edge portion of the upper layer and the edge portion of the lower layer, each of a length of the edge portion of the upper layer and a length of the edge portion of the lower layer is less than or equal to about 50 μm.

According to embodiments of the disclosure, the edge portion of the cover window may be completely filled with the resin, thereby removing or reducing a difference in visibility between the central portion and the edge portion of the cover window.

Accordingly, a black matrix disposed on the edge portion of the cover window may be removed or reduced, thereby reducing a dead space.

### BRIEF DESCRIPTION OF THE DRAWINGS

The above and other features of the disclosure will become more apparent by describing in further detail embodiments thereof with reference to the accompanying drawings.

FIG. 1 is an exploded perspective view of a display device according to an embodiment.

FIG. 2 is a schematic cross-sectional view of a cover window taken along line X-X′ in FIG. 1.

FIG. 3 is a schematic cross-sectional view of the cover window taken along line Y-Y′ in FIG. 1.

FIG. 4 is a plan view of an upper layer and a lower layer according to an embodiment.

FIG. 5 is a schematic cross-sectional view of the cover window according to an embodiment.

FIG. 6 is a step diagram illustrating a method of manufacturing the cover window according to an embodiment.

FIGS. 7, 8, 9, 10, 11, 12, 13, 14 and 15 are schematic cross-sectional views illustrating a method of manufacturing the cover window according to an embodiment.

### DETAILED DESCRIPTION OF THE EMBODIMENT

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. Herein, the term “dead space” may be understood as a space which is devoted to accommodating one or more components that, either singularly or plurally, perform an intended function.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure are described in detail with reference to the accompanying drawings.

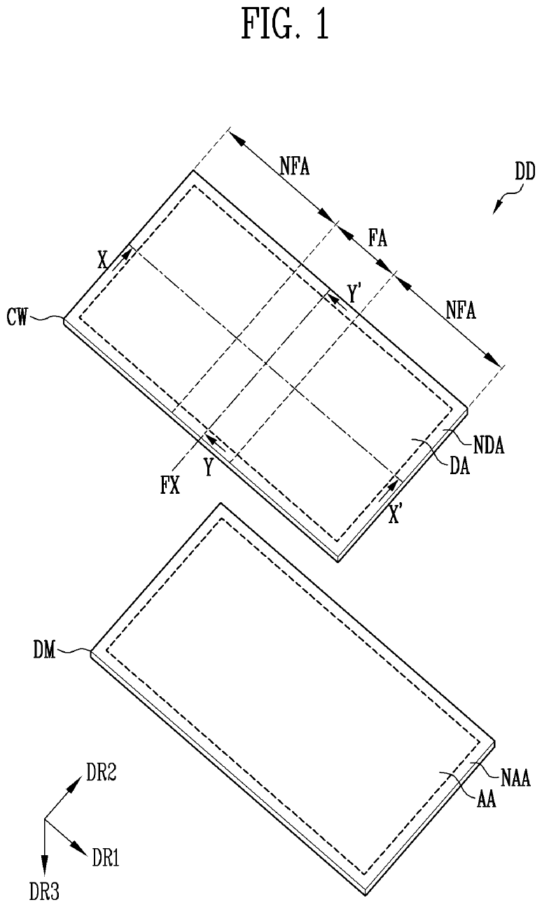

FIG. 1 is an exploded perspective view of a display device DD according to an embodiment of the disclosure.

Referring to FIG. 1, the display device DD may include a display module DM and a cover window CW.

The display device DD may be a device that is activated according to an electrical signal to provide an image. The display device DD may be implemented with various electronic devices to display an image. For example, the display device DD may be implemented with a large-sized electronic device such as a television and a monitor, and a small and medium-sized electronic device such as a mobile phone, a tablet, a car navigation system, and a game console. However, the display device DD is not limited to the above-described examples and may be implemented with various electronic devices.

The display device DD may be flexible. “Flexible” may mean a property of being able to be bent, and may include a completely foldable structure to a structure that may be bent at a level of a few nanometers. For example, the display device DD may be a foldable display device. In another embodiment, the display device DD may be rigid.

The display module DM may display an image according to an electrical signal and may transmit and receive information through an external input. The display module DM may include an active area AA and a peripheral area NAA.

The active area AA may be an area activated according to the electrical signal. For example, the display module DM may display an image or sense various types of external inputs through the active area AA.

The peripheral area NAA may be disposed adjacent to the active area AA. For example, the peripheral area NAA may surround the active area AA in a plan view. However, the disclosure is not limited thereto, and the peripheral area NAA may be defined in various forms, such as being adjacent to a side of the active area AA.

The display module DM may include a display panel. The display panel may generate an image displayed from the display module DM. The display panel may be a light emitting display panel, but the disclosure is limited thereto. For example, the display panel may be an organic light emitting display panel or a quantum dot light emitting display panel. In an embodiment, the display module DM may further include an input sensor disposed on the display panel and sensing the external input.

The display module DM may include multiple pixels disposed in the active area AA and a circuit unit disposed in the peripheral area NAA. The circuit unit may provide an electrical signal to the pixels to drive the pixels. The pixels may be formed by arranging light emitting patterns in the active area AA. The light emitting patterns of the pixels receiving an electrical signal from the circuit unit may emit light in response to the electrical signal, and thus may output an image in the active area AA.

The cover window CW may be disposed on the display module DM. The cover window CW may cover the entire upper surface of the display module DM. For example, a shape of the cover window CW may correspond to a shape of the display module DM. The cover window CW may alleviate an external impact, and prevent the display module DM from being damaged or malfunctioning due to the external impact.

The cover window CW may include an optically transparent material. The cover window CW may include an optically transparent substrate described below. For example, the cover window CW may include a glass substrate, and the glass substrate may be a tempered glass substrate.

The cover window CW may have a single-layer structure or a multi-layer structure. For example, the cover window CW may have a single-layer structure including a glass substrate, but the disclosure is not limited thereto, and the cover window CW may have a multi-layer structure including a coating film coated on a glass substrate, a filling member, or a polymer film disposed on a glass substrate.

A front surface of the cover window CW may correspond to a front surface of the display device DD. The cover window CW may include a display area DA and a non-display area NDA.

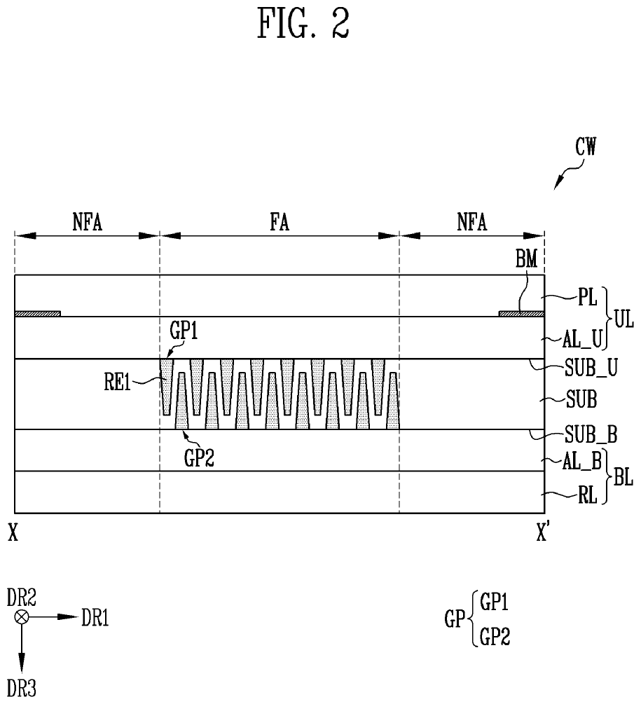

The display area DA of the cover window CW may transmit an image emitted from the display module DM. A user may visually recognize the image through the display area DA of the cover window CW. The cover window CW may have a color in the non-display area NDA. For example, the cover window CW may include a black matrix BM (refer to FIG. 2) on the glass substrate in the non-display area NDA.

The cover window CW may be flexible. The cover window CW may be foldable together with the display module DM around a folding axis FX. In case that the cover window CW is foldable around the folding axis FX, the cover window CW may include a folding area FA that is bendable with a curvature and a non-folding area NFA disposed adjacent to the folding area FA. For example, the folding area FA and the non-folding area NFA may be arranged in a first direction DR1.

FIG. 1 illustrates that the cover window CW has a rectangular shape in a plan view. However, the disclosure is not limited thereto, and the cover window CW may have various shapes corresponding to the display module DM. For example, the cover window CW may have a quadrangular shape with rounded corners. As described above, a shape of the cover window CW may vary according to a design of a substrate manufactured through a manufacturing process of the cover window CW.

Although not separately shown, the display device DD may further include at least one functional layer disposed between the display module DM and the cover window CW. For example, the display device DD may include an anti-reflection layer that reduces reflectance of external light incident from an upper side of the cover window CW.

FIG. 2 is a schematic cross-sectional view of the cover window CW taken along line X-X′ in FIG. 1.

Referring to FIG. 2, the cover window CW may include a substrate SUB, an upper layer UL, and a lower layer BL.

The substrate SUB may include a folding area FA foldable with a curvature around the folding axis FX (refer to FIG. 1) and a non-folding area NFA disposed adjacent to the folding area FA. The non-folding area NFA may be disposed adjacent to both sides of the folding area FA in the first direction DR1. The number of folding areas FA and non-folding areas NFA included in the substrate SUB is not limited to the embodiment shown in FIG. 2.

The substrate SUB may include an upper surface SUB_U and a lower surface SUB_B. The upper surface SUB_U and the lower surface SUB_B of the substrate SUB may be parallel to a plane defined by the first direction DR1 and a second direction DR2 intersecting the first direction DR1. The upper surface SUB_U and the lower surface SUB_B of the substrate SUB may face each other in a third direction DR3 intersecting the first direction DR1 and the second direction DR2.

The substrate SUB may include an optically transparent material. In an embodiment, the substrate SUB may include a glass substrate. In another embodiment, the substrate SUB may include a tempered glass substrate on which tempering is processed. Since the substrate SUB includes a glass substrate, aesthetics may be excellent, and a dent, a scratch, or the like due to contact with a sharp material may be prevented.

Groove patterns GP may be formed on the substrate SUB. The groove patterns GP may be formed on the substrate SUB corresponding to the folding area FA. The groove patterns GP may be defined in the folding area FA of the substrate SUB. For example, the groove patterns GP may be disposed in the folding area FA of the substrate SUB. FIG. 2 illustrates that 16 groove patterns GP are formed in the folding area FA. However, the number of groove patterns GP is not limited to the shown embodiment, and the substrate SUB may include less or greater number of groove patterns GP.

The groove patterns GP may be arranged in a direction intersecting the folding axis FX (refer to FIG. 1). For example, the groove patterns GP may be arranged in the first direction DR1 intersecting the folding axis FX.

The groove patterns GP may extend in a direction parallel to the folding axis FX. For example, the groove patterns GP may extend in the second direction DR2 parallel to the folding axis FX. However, the disclosure is not limited thereto, and the groove patterns GP may obliquely extend with respect to the folding axis FX so as to intersect a direction parallel to the folding axis FX.

The groove patterns GP may include first groove patterns GP1 and second groove patterns GP2.

The first groove patterns GP1 may be formed by recessing portions of the substrate SUB from the upper surface SUB_U to the lower surface SUB_B of the substrate SUB. Each of the first groove patterns GP1 may be recessed from the upper surface SUB_U of the substrate SUB and may be defined by a bottom surface and a side surface connected to the upper surface SUB_U of the substrate SUB. Each of the first groove patterns GP1 may include a bottom surface parallel to the upper surface SUB_U of the substrate SUB and a side surface connecting the bottom surface of the first groove pattern GP1 and the upper surface SUB_U of the substrate SUB. The side surface of each of the first groove patterns GP1 may form an angle with the upper surface SUB_U of the substrate SUB. However, the disclosure is not limited thereto, and the side surface of each of the first groove patterns GP1 may include at least one curved surface.

The first groove patterns GP1 may be spaced apart from each other with a portion of the upper surface SUB_U of the substrate SUB interposed between adjacent first groove patterns GP1. FIG. 2 illustrates that the first groove patterns GP1 are arranged and spaced apart from each other in the first direction DR1. However, the disclosure is not limited thereto, and at least some of the first groove patterns GP1 may cross each other and may be connected to be integrally formed. A shape and an arrangement of the first groove patterns GP1 may be variously implemented.

The second groove patterns GP2 may be formed by recessing portions of the substrate SUB from the lower surface SUB_B to the upper surface SUB_U of the substrate SUB. Each of the second groove patterns GP2 may be recessed from the lower surface SUB_B of the substrate SUB and may be defined by a bottom surface and a side surface connected to the lower surface SUB_B of the substrate SUB. Each of the second groove patterns GP2 may include a bottom surface parallel to the lower surface SUB_B of the substrate SUB and a side surface connecting the bottom surface of the second groove pattern GP2 and the lower surface SUB_B of the substrate SUB. The side surface of each of the second groove patterns GP2 may form an angle with the lower surface SUB_B of the substrate SUB. However, the disclosure is not limited thereto, and the side surface of each of the second groove patterns GP2 may include at least one curved surface.

The second groove patterns GP2 may be spaced apart from each other with a portion of the lower surface SUB_B of the substrate SUB interposed between adjacent second groove patterns. In an embodiment, the first groove patterns GP1 and the second groove patterns GP2 may be alternately arranged. FIG. 2 illustrate that the second groove patterns GP2 are spaced apart from each other in the first direction DR1 and alternately arranged with the first groove patterns GP1. However, the disclosure is not limited thereto, at least some of the second groove patterns GP2 may cross each other and may be connected to be integrally formed. A shape and an arrangement of the second groove patterns GP2 may be variously implemented.

As the groove patterns GP are formed in the folding area FA, a folding characteristic of the cover window CW may be improved. A thickness of a portion of the substrate SUB in the folding area FA may become relatively thin, and flexibility of the substrate SUB may be improved by the groove patterns GP. In case that the cover window CW is folded, the folding area FA of the substrate SUB may be bent with a curvature, and compressive or tensile stress may be applied to the substrate SUB in the folding area FA. The groove patterns GP may reduce the compressive or tensile stress applied to the substrate SUB to prevent damage due to folding of the substrate SUB.

In an embodiment, the groove patterns GP may be filled with a resin. For example, the first groove patterns GP1 and the second groove patterns GP2 may be filled with a first resin RE1. In an embodiment, the first resin RE1 and the substrate SUB may have a same refractive index, and a viscosity of the first resin RE1 may be less than or equal to about 20 cps. Because the first resin RE1 is discharged from an upper side of the groove patterns GP, the first resin RE1 may have a low viscosity. Since the groove patterns GP are filled with a resin, the groove patterns GP may be prevented from being visually recognized by the user.

The upper layer UL may be disposed on the upper surface SUB_U of the substrate SUB. In an embodiment, the upper layer UL may include an upper adhesive layer AL_U and a protective layer PL.

The upper adhesive layer AL_U may be disposed on the upper surface SUB_U of the substrate SUB. The upper adhesive layer AL_U may be disposed between the substrate SUB and the protective layer PL. The upper adhesive layer AL_U may be optically transparent. The upper adhesive layer AL_U may include an optically clear adhesive (OCA), an optically clear resin (OCR), or a pressure sensitive adhesive (PSA). The substrate SUB and the protective layer PL may be coupled by the upper adhesive layer AL_U.

The protective layer PL may be disposed on the upper adhesive layer AL_U. The protective layer PL may protect the cover window CW from an external impact. The protective layer PL may include a synthetic resin material. For example, the protective layer PL may include at least one of a urethane-based resin, an epoxy-based resin, a polyester-based resin, a polyether-based resin, an acrylate-based resin, an acrylonitrile-butadiene-styrene (ABS) resin, and rubber. For example, the protective layer PL may include at least one of phenylene, polyethyleneterephthalate (PET), polyimide (PI), polyamide (PAI), polyethylene naphthalate (PEN), and polycarbonate (PC).

A print layer may be disposed under the protective layer PL. For example, the print layer may be a black matrix BM. The black matrix BM may be disposed to overlap an edge of the protective layer PL in the third direction DR3 (or in a plan view). The black matrix BM may include an organic light blocking material or an inorganic light blocking material including a black pigment or dye. However, the disclosure is not limited thereto, and a color of the print layer may be a color other than black.

The lower layer BL may be disposed on the lower surface SUB_B of the substrate SUB. In an embodiment, the lower layer BL may include a lower adhesive layer AL_B and a release layer RL.

The lower adhesive layer AL_B may be disposed on the lower surface SUB_B of the substrate SUB. The lower adhesive layer AL_B may be disposed between the substrate SUB and the release layer RL. The lower adhesive layer AL_B may be optically transparent. The lower adhesive layer AL_B may include an OCA, an OCR, or a PSA. The substrate SUB and the release layer RL may be coupled by the lower adhesive layer AL_B.

The release layer RL may be disposed on the lower adhesive layer AL_B. The release layer RL may protect the cover window CW during a transportation process of the cover window CW. The release layer RL may be removed from the cover window CW during a manufacturing process of the display device DD. Accordingly, the cover window CW may be coupled to the display module DM (refer to FIG. 1) by the lower adhesive layer AL_B.

The release layer RL may include transparent glass or transparent plastic. For example, the release layer RL may include glass, ultra thin glass (UTG), polyethyleneterephthalate (PET), polyimide (PI), polyethersulphone (PS), polyacrylate (PA), polyetherimide (PEI), polyethylenenaphthalate (PEN), polyphenylene sulfide (PPS), polyarylate (PAR), polycarbonate (PC), poly (aryleneether sulfone), or the like.

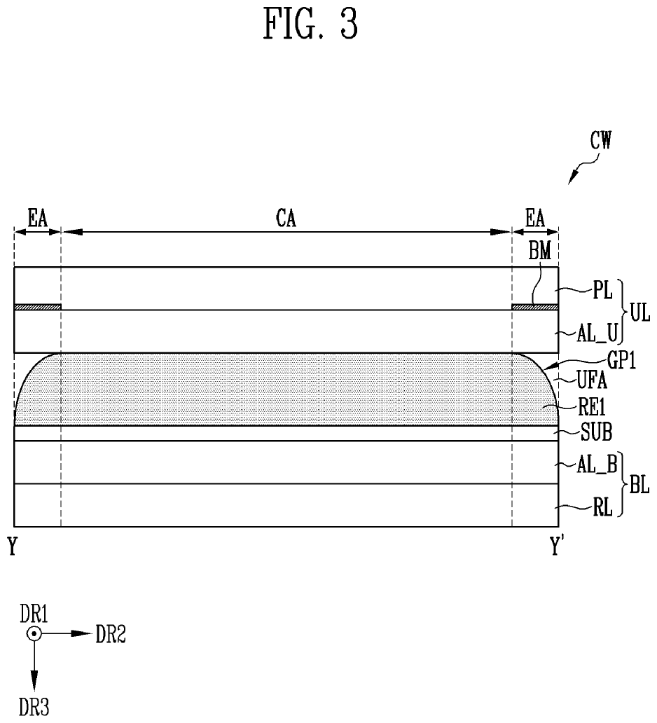

FIG. 3 is a schematic cross-sectional view of the cover window CW taken along line Y-Y′ in FIG. 1. For convenience of description, a cross-sectional view of the cover window CW including one of the first groove patterns GP1 is schematically illustrated in FIG. 3.

Referring to FIG. 3, the first groove patterns GP1 (refer to FIG. 2) may each include a central portion CA formed at a center of the first groove pattern GP1 and an edge portion EA disposed adjacent to the central portion CA. For example, the central portion CA of the first groove pattern GP1 may extend from a center of the first groove pattern GP1 to edge portions EA of the first groove pattern GP1 in a length direction of the first groove pattern GP1. For example, a length of the central portion CA of the first groove pattern GP1 is greater than or equal to about 90% of a length of the first groove pattern GP1 in the length direction. For example, the length of the central portion CA of the first groove pattern GP is greater than or equal to about 95% of the length of the first groove pattern GP1. For example, the length of the central portion CA of the first groove pattern GP is greater than or equal to about 99% of the length of the first groove pattern GP1.

The central portion CA of each of the first groove patterns GP1 may be filled (or completely filled) with the first resin RE1, and thus the first groove patterns GP1 of the central portion CA may not be visually recognized by the user. Since the first resin RE1 is discharged in a form of a droplet from an upper side of each of the first groove patterns GP1, the edge portion EA of each of the first groove patterns GP1 may not be completely filled with the first resin RE1. For example, an unfilled area UFA may be generated at the edge portion EA of each of the first groove patterns GP1, and thus the first groove patterns GP1 in the edge area EA may be visually recognized by the user. As a result, a difference in visibility between the central portion CA and the edge portion EA of the first groove patterns GP1 may occur, and thus visibility may be deteriorated.

In order to prevent the above-described deterioration in visibility, the black matrix BM that covers the unfilled area UFA may be disposed under the protective layer PL. For example, the black matrix BM may overlap the unfilled area UFA in the third direction DR (or in a plan view). However, to effectively cover the unfilled area UFA, the black matrix BM of greater than 2 mm may be required to be disposed. In case that an excessive black matrix BM is applied, a dead space may increase successively.

The above-described contents may be equally applied to the second groove patterns GP2 (refer to FIG. 2). For example, while the central portion of each of the second groove patterns GP2 may be completely filled with the first resin RE1, the edge portion may not be completely filled with the first resin RE1, and thus the unfilled area UFA may be generated.

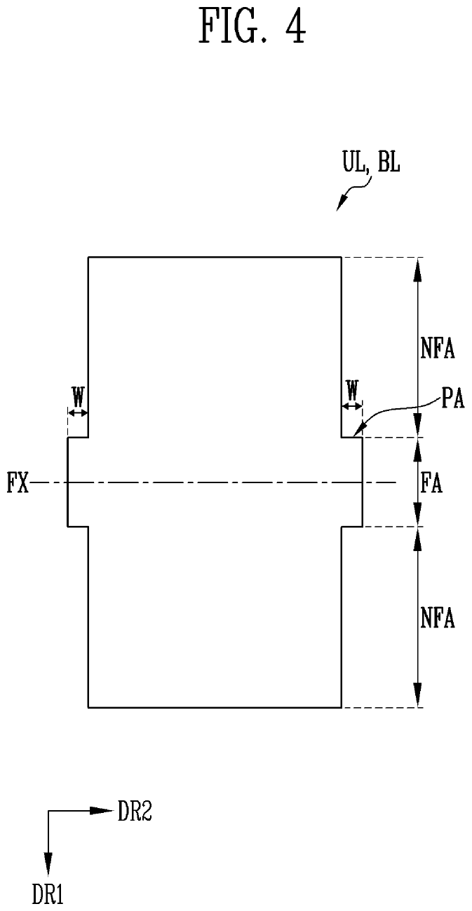

FIG. 4 is a plan view of the upper layer UL and the lower layer BL according to an embodiment.

Referring to FIG. 4, the upper layer UL and the lower layer BL may include the folding area FA foldable around the folding axis FX with a curvature and the non-folding area NFA disposed adjacent to the folding area FA, similarly to the substrate SUB. The non-folding area NFA may be disposed adjacent to both sides of the folding area FA in the first direction DR1.

In an embodiment, the upper layer UL may include an edge portion PA protruding from the folding area FA of the upper layer UL. For example, the edge portion PA of the upper layer UL may protrude from the folding area FA in a direction parallel to the folding axis FX. In an embodiment, the lower layer BL may include an edge portion PA protruding from the folding area FA of the lower layer BL. For example, the edge portion PA of the lower layer BL may protrude from the folding area FA in a direction parallel to the folding axis FX.

In an embodiment, the edge portion PA of the upper layer UL and the lower layer BL corresponding to the folding area FA may have a same length w in a direction parallel to the folding axis FX. For example, each of the upper layer UL and the lower layer BL may include an edge portion PA having a same shape in a plan view. The length w of an edge portion PA be less than or equal to about 50 μm.

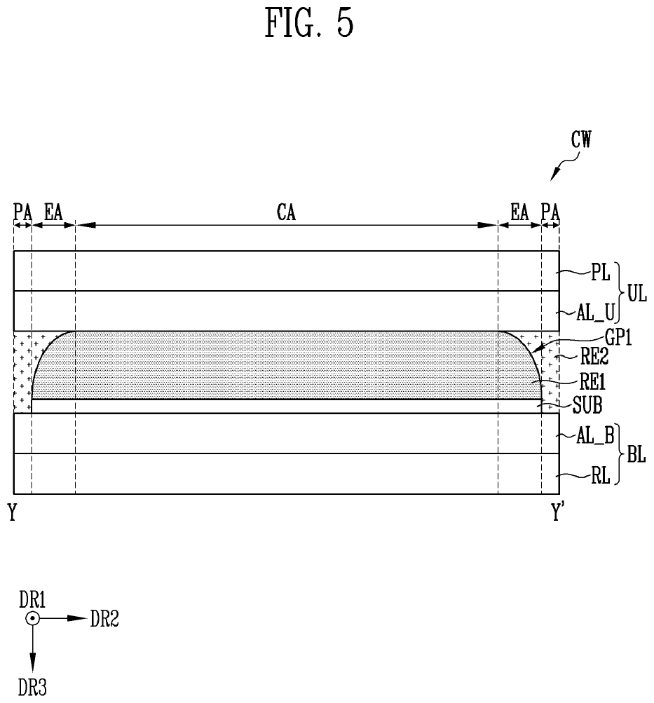

FIG. 5 is a schematic cross-sectional view of the cover window CW according to an embodiment. FIG. 5 is schematic cross-sectional view of the cover window CW taken along line Y-Y′ in FIG. 1 according to another embodiment. For convenience of description, a cross-sectional view of the cover window CW including one of the first groove patterns GP1 is schematically illustrated in FIG. 5.

Referring to FIG. 5, each of the first groove patterns GP1 may be filled (for example, completely filled) with a resin. For example, the central portion CA of the first groove patterns GP1 may be filled with the first resin RE1. In an embodiment, the edge portion EA of the first groove patterns GP1 may be filled with the first resin RE1 and a second resin RE2 different from the first resin RE1. For example, the unfilled area UFA (refer to FIG. 3) generated at the edge portion EA of the first groove patterns GP1 may be filled with the second resin RE2. Accordingly, a difference in visibility between the central portion CA and the edge portion EA of the first groove patterns GP1 may be removed, and thus visibility may be improved.

Since the unfilled area UFA is filled with the second resin RE2 and the edge portion EA of each of the first groove patterns GP1 is not visually recognized by the user, a dead space may be reduced by omitting or reducing the black matrix BM (refer to FIG. 3) disposed under the protective layer PL.

In an embodiment, the second resin RE2 and the substrate SUB may have a same refractive index, and a viscosity of the second resin RE2 may be greater than or equal to about 2000 cps. Since the second resin RE2 is discharged from a side surface of the groove patterns GP, the second resin RE2 may have a higher viscosity different from the first resin RE1 discharged from the upper side of the groove patterns GP.

The second resin RE2 may be disposed between the edge portion PA of the upper layer UL and the edge portion PA of the lower layer BL. Accordingly, the edge portion PA of the upper layer UL, the edge portion PA of the lower layer BL, and the second resin RE2 may protrude with a same length w (refer to FIG. 4).

The above-described contents may be equally applied to the second groove patterns GP2 (refer to FIG. 2). For example, an edge portion EA of each of the second groove patterns GP2 may be completely filled with the first resin RE1 and the second resin RE2, and thus the unfilled area UFA may be removed.

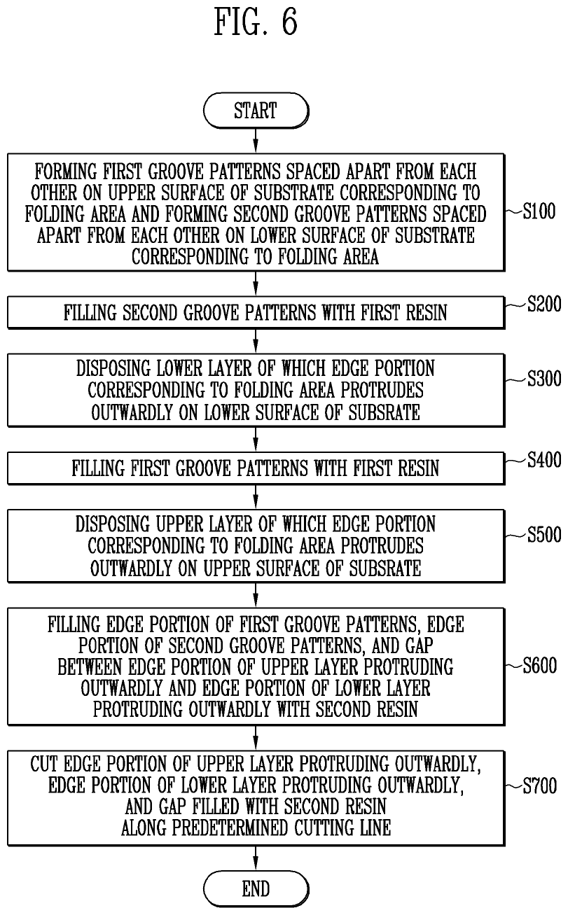

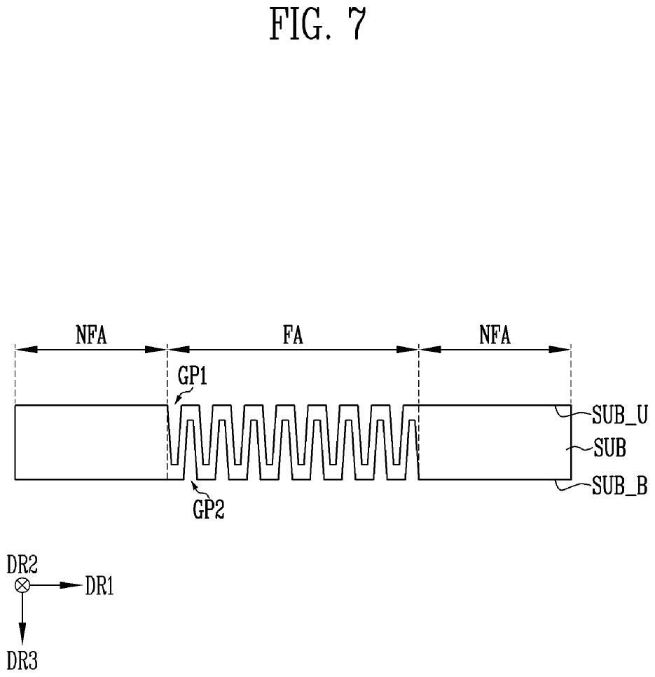

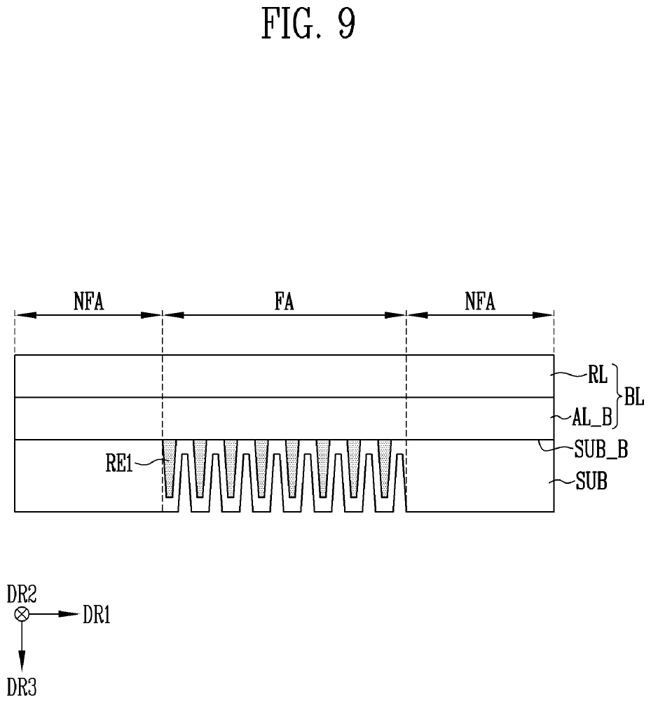

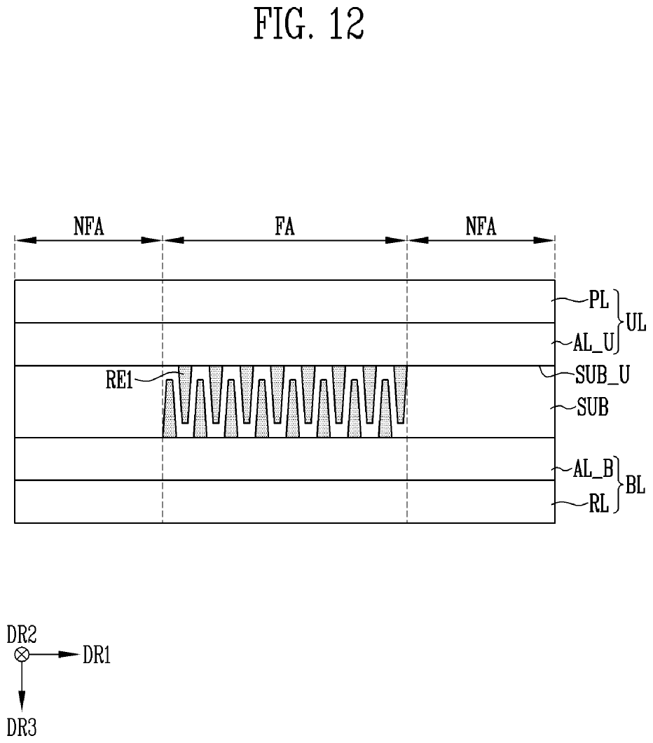

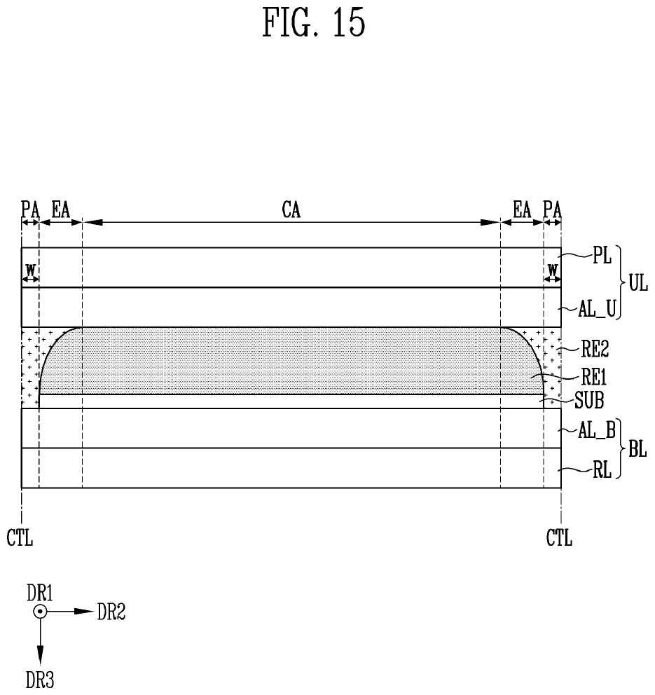

FIG. 6 is a step diagram illustrating a method of manufacturing the cover window CW according to an embodiment. FIGS. 7 to 15 are schematic cross-sectional views illustrating a method of manufacturing the cover window CW according to an embodiment.

Referring to FIGS. 6 and 7, in step S100, the groove patterns GP may be formed on the substrate SUB corresponding to the folding area FA. For example, in step S100, the first groove patterns GP1 spaced apart from each other may be formed on the upper surface SUB_U of the substrate SUB in the folding area FA. For example, in step S100, the second groove patterns GP2 spaced apart from each other may be formed on the lower surface SUB_B of the substrate SUB corresponding to the folding area FA. Since an arrangement or a shape of the groove patterns GP is the same as described above, a detailed description is omitted.

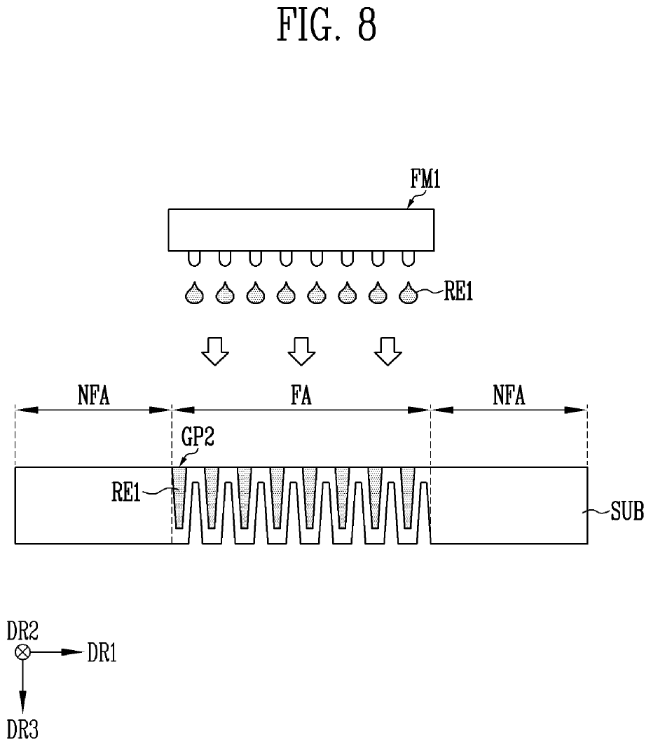

Referring to FIGS. 6 and 8, in step S200, the first resin RE1 may be filled in the second groove patterns GP2. The first resin RE1 may be discharged from a first filler FM1 disposed above the second groove patterns GP2. In an embodiment, the first filler FM1 may be an inkjet printing device. The first resin RE1 may be discharged in the form of the droplet through a nozzle of the first filler FM1 and provided on the second groove patterns GP2. As described above, since the first resin RE1 is discharged in a direction of gravity, the first resin RE1 may have a low viscosity, for example, less than or equal to about 20 cps.

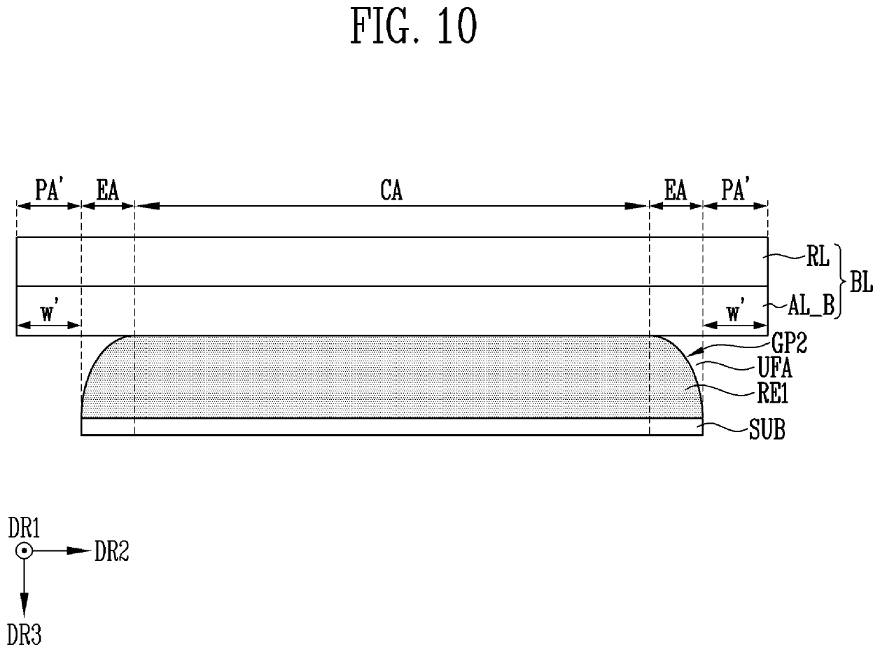

Referring to FIG. 10, the central portion CA of the second groove patterns GP2 may be filled with the first resin RE1. The edge portion EA of the second groove patterns GP2 may be filled with the first resin RE1. Since the first resin RE1 is discharged in the form of the droplet, an unfilled area UFA may be formed at the edge portion EA of the second groove patterns GP2.

Referring to FIGS. 6, 9, and 10, in step S300, the lower layer BL including an edge portion PA′ in the folding area FA may be disposed on the lower surface SUB_B of the substrate SUB. The lower layer BL may include the lower adhesive layer AL_B disposed on the lower surface SUB_B of the substrate SUB and the release layer RL disposed on the lower adhesive layer AL_B.

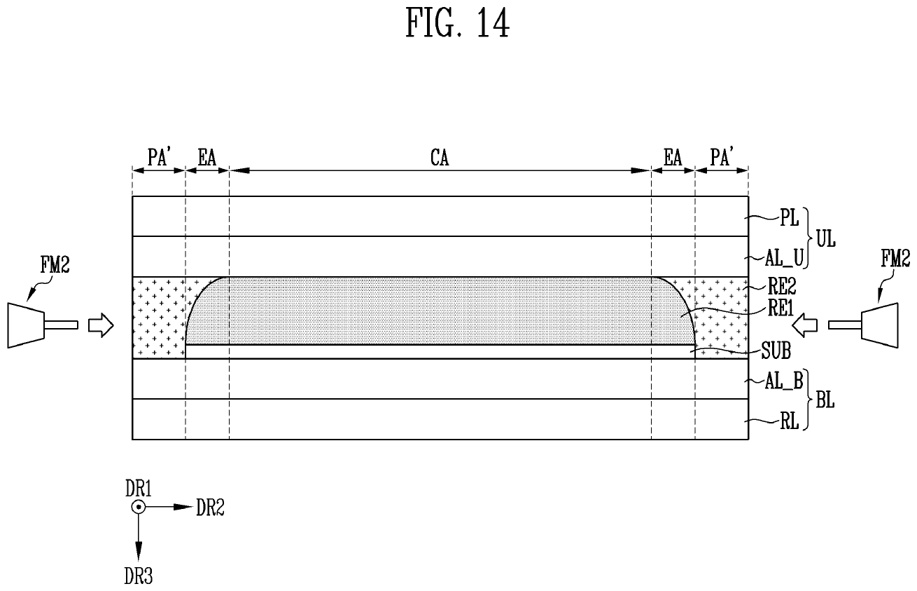

In an embodiment, a length w′ of the edge portion PA′ of the lower layer BL in a direction parallel to the folding axis FX may be in a range of about 1.5 mm to about 4 mm, and the length w′ may be a value set in consideration of a flow according to the viscosity of the second resin RE2 (FIG. 14) filled from a side surface as described below.

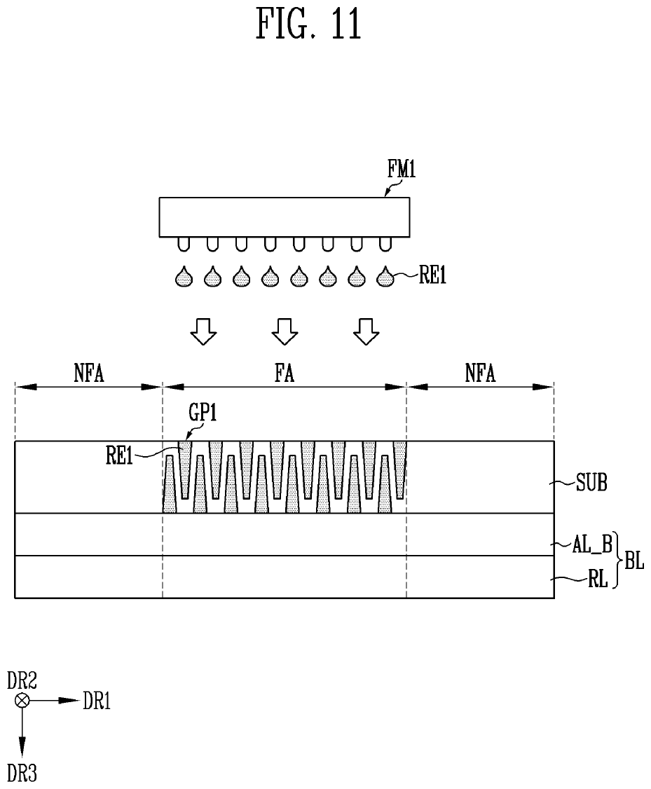

Referring to FIGS. 6 and 11, in step S400, the first resin RE1 may be filled in the first groove patterns GP1. Similar to step S200, the first resin RE1 may be discharged from the first filler FM1 disposed above the first groove patterns GP1. For example, the first resin RE1 may be discharged in the form of a droplet through the nozzle of the first filler FM1 and provided on the first groove patterns GP1. A viscosity characteristic of the first resin RE1 is the same as described above.

Referring to FIGS. 6, 12, and 13, in step S500, the upper layer UL including the edge portion PA′ in the folding area FA may be disposed on the upper surface SUB_U of the substrate SUB. The upper layer UL may include an upper adhesive layer AL_U disposed on the upper surface SUB_U of the substrate SUB and a protective layer PL disposed on the upper adhesive layer AL_U.

In an embodiment, a length w′ of the edge portion PA′ of the upper layer UL in a direction parallel to the folding axis FX may be in a range of about 1.5 mm to about 4 mm, and the length w′ may be a value set in consideration of a flow according to the viscosity of the second resin RE2 (refer to FIG. 14) filled from a side surface as described above.

The edge portion PA′ of the upper layer UL and the lower layer BL may function of stably filling the unfilled area UFA generated at the edge portion EA of each of the groove patterns GP with the second resin RE2 (refer to FIG. 14). For example, the edge portion PA′ of the upper layer UL and the lower layer BL may serve as a dam which prevents the second resin RE2 from flowing outwardly in case that the second resin RE2 is filled.

As the edge portion PA′ of the upper layer UL and the lower layer BL protrude, a gap may be formed between the edge portions PA′ of the upper layer UL and the lower layer BL.

Referring to FIGS. 6 and 14, in step S600, the second resin RE2 different from the first resin RE1 may be filled in the edge portion EA of the first groove patterns GP1, the edge portion EA of the second groove patterns GP2, and between the edge portion PA′ of the upper layer UL and the edge portion PA′ of the lower layer BL.

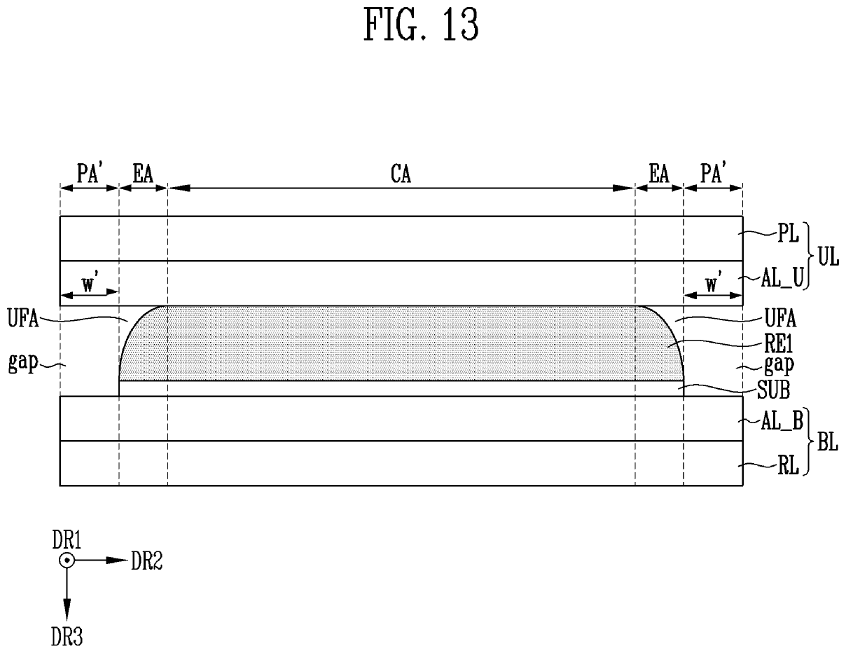

The second resin RE2 may be discharged from a second filler FM2 disposed at a of the first groove patterns GP1 and the second groove patterns GP2. In an embodiment, the second filler FM2 may be a jetting valve. The second resin RE2 may be discharged to a side surface of the first groove patterns GP1 and the second groove patterns GP2 through a nozzle of the second filler FM2 and provided to the unfilled area UFA and the gap (refer to FIG. 13). As described above, since the second resin RE2 is discharged in a direction intersecting the direction of gravity differently from the first resin RE1, a high viscosity of greater than or equal to about 2000 cp may be required.

Accordingly, since the edge portions EA of the first groove patterns GP1 and the second groove patterns GP2 including the central portion CA are completely filled with the resin RE, a difference in visibility between the central portion CA and the edge portion EA of the cover window CW may be reduced, and thus visibility may be improved.

Referring to FIGS. 6, 14, and 15, in step S700, the edge portion PA′ of the upper layer UL, the edge portion PA′ of the lower layer BL, and the gap filled with the second resin RE2 may be cut along a cutting line CTL.

After the second resin RE2 is filled, the edge portions PA′ of the upper layer UL and the lower layer BL may function as align marks. Since the cover window CW is positioned at the uppermost end of the display device DD and is visually recognized by the user (refer to FIG. 1), applying an alignment mark for cutting to the cover window CW may be difficult. According to an embodiment, a cutting process may be readily performed without a separate alignment mark by using the edge portion PA′ of the upper layer UL and the lower layer BL as an alignment mark.

In an embodiment, the edge portion PA′ of the upper layer UL, the edge portion PA′ of the lower layer BL, and the gap filled with the second resin RE2 may be cut so as to protrude less than or equal to about 50 μm. For example, the lengths of the edge portion PA of the upper layer UL, the edge portion PA of the lower layer BL, and the gap filled with the second resin RE2 remaining after cutting may be less than or equal to about 50 μm in a direction. Accordingly, a step difference w (refer to FIG. 4) between the folding area FA and the non-folding area NFA of the upper layer UL and the lower layer BL may be minimized.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A cover window comprising:
a folding area and a non-folding area arranged in a first direction; and
groove patterns formed on a substrate in the folding area, arranged in the first direction, and extending in a second direction intersecting the first direction, wherein
a central portion of the groove patterns is filled with a first resin, and
an edge portion of the groove patterns is filled with the first resin and a second resin different from the first resin.

2. The cover window according to claim 1, wherein
a viscosity of the first resin is less than or equal to about 20 cp, and
a viscosity of the second resin is greater than or equal to about 2000 cp.

3. The cover window according to claim 1, further comprising:
an upper layer disposed on an upper surface of the substrate and having an edge portion protruding from the folding area of the upper layer; and
a lower layer disposed on a lower surface of the substrate and having an edge portion protruding from the folding area of the lower layer,
wherein a gap between the edge portion of the upper layer and the edge portion of the lower layer is filled with the second resin.

4. The cover window according to claim 3, wherein a length of the edge portion of the upper layer and a length of the edge portion of the lower layer in the second direction are same.

5. The cover window according to claim 4, wherein each of the length of the edge portion of the upper layer and the length of the edge portion of the lower layer is less than or equal to about 50 μm.

6. The cover window according to claim 1, wherein the groove patterns comprise:
first groove patterns spaced apart from each other and formed on an upper surface of the substrate; and
second groove patterns spaced apart from each other and formed on a lower surface of the substrate.

7. The cover window according to claim 6, wherein the first groove patterns and the second groove patterns are alternately arranged in the first direction.

8. The cover window according to claim 3, wherein the upper layer comprises:
an upper adhesive layer disposed on the upper surface of the substrate; and
a protective layer disposed on the upper adhesive layer.

9. The cover window according to claim 3, wherein the lower layer comprises:
a lower adhesive layer disposed on the lower surface of the substrate; and
a release layer disposed on the lower adhesive layer.

10. A method of manufacturing a cover window including a folding area and a non-folding area arranged in a first direction, the method comprising:
forming first groove patterns spaced apart from each other on an upper surface of a substrate in the folding area,
forming second groove patterns spaced apart from each other on a lower surface of the substrate in the folding area;
filling the first groove patterns with a first resin;
disposing an upper layer including an edge portion protruding from the folding area of the upper layer on the upper surface of the substrate;
filling the second groove patterns with the first resin;
disposing a lower layer including an edge portion protruding from the folding area of the lower layer on the lower surface of the substrate; and
filling a gap between the edge portion of the upper layer and the edge portion of the lower layer with a second resin different from the first resin.

11. The method according to claim 10, wherein the first groove patterns and the second groove patterns are alternatively arranged in the first direction and extend in a second direction intersecting the first direction.

12. The method according to claim 10, wherein
a central portion of the first groove patterns and a central portion of the second groove patterns are filled with the first resin, and
an edge portion of the first groove patterns and an edge portion of the second groove patterns are filled with the first resin and the second resin.

13. The method according to claim 10, wherein
a viscosity of the first resin is less than or equal to about 20 cp, and
a viscosity of the second resin is greater than or equal to about 2000 cp.

14. The method according to claim 10, wherein the first resin is discharged from a first filler disposed above the first groove patterns and the second groove patterns.

15. The method according to claim 14, wherein the first filler is an inkjet printing device.

16. The method according to claim 10, wherein the second resin is discharged from a second filler disposed at a side of the first groove patterns and the second groove patterns.

17. The method according to claim 16, wherein the second filler is a jetting valve.

18. The method according to claim 10, wherein each of a length of the edge portion of the upper layer and a length of the edge portion of the lower layer is in a range of about 1.5 mm to about 4 mm.

19. The method according to claim 10, further comprising:
cutting the edge portion of the upper layer and the edge portion of the lower layer along a cutting line.

20. The method according to claim 19, wherein after the cutting of the edge portion of the upper layer and the edge portion of the lower layer, each of a length of the edge portion of the upper layer and a length of the edge portion of the lower layer is less than or equal to about 50 μm.
